(19) United States
(12) Patent Application Publication
(10) Pub. No.: US 2011/0110391 A1
(43) Pub. Date: May 12, 2011

(54) SEMICONDUCTOR LASER DIODE HAVING WAVEGUIDE LENS

(75) Inventors: Kwang-Ryong Oh, Daejeon (KR); Dong-Churl Kim, Daejeon (KR); Kisoo Kim, Daejeon (KR)

(73) Assignee: Electronics and Telecommunications Research Institute, Daejeon (KR)

(21) Appl. No.: 13/002,026

(22) PCT Filed: Nov. 24, 2008
(86) PCT No.: PCT/KR2008/006917

§ 371 Date: Dec. 29, 2010

(30) Foreign Application Priority Data
Jul. 16, 2008 (KR) 10-2008-0069129

(51) Int. Cl. H01S 5/323; H01S 5/10

(52) U.S. Cl. 372/45.01; 372/50.23

(57) ABSTRACT

Provided is a semiconductor laser diode having a waveguide lens. The semiconductor laser diode includes at least one first waveguide having a narrow width, at least one second waveguide having a wide width wider, and at least one waveguide lens having an increasing width from the first waveguide toward the second waveguide and connecting the first waveguide to the second waveguide. Sidewalls of the waveguide lens connecting the first waveguide to the second waveguide may be curved. The second waveguide may be a waveguide providing an optical gain.

### TECHNICAL FIELD

The present invention disclosed herein relates to a semiconductor laser diode, and more particularly, to a semiconductor laser diode having a waveguide lens.

2. Background Art

To realize a single mode, suggested are semiconductor laser diodes, whose waveguide has a width of an about several micro meter or less. However, in the case of such a semiconductor laser diode having a narrow waveguide, the damage of a waveguide section due to a high output and the saturation of an optical output suppress output to be below a W-level.

FIG. 1 is a plan view illustrating a typical semiconductor laser diode to address these technical limitations.

Referring to FIG. 1, a resonator 10 of a typical laser semiconductor includes a gain waveguide 1 having a narrow width (hereinafter, a narrow waveguide), and a gain waveguide 2 having an increasing width (hereinafter, a tapered waveguide). The tapered waveguide 2 with a linearly increasing width extends from the narrow waveguide 1. The narrow waveguide 1 may have a width ranging from about 1 micro meter to about 2 micro meter, and the tapered waveguide 2 may have a maximum width ranging from about several micro meter to about a hundred micro meter.

Since the width of the tapered waveguide 2 is increased to about a hundred micro meter, the output of an incident beam from the narrow waveguide 1 to the tapered waveguide 2 is even greater than that of a semiconductor laser diode having a width of several micro meter. However, in the case of the typical laser semiconductor, since the tapered waveguide 2 has a straight line-shaped and tapered boundary as illustrated in FIG. 1, it is difficult to effectively guide a beam traveling from the tapered waveguide 2 to the narrow waveguide 1. Accordingly, only a portion of beams traveling from the tapered waveguide 2 to the narrow waveguide 1 is contributed to laser oscillation, and such beam loss suppresses improved efficiency of output to a current input and a threshold current of the laser oscillation.

Meanwhile, a beam output from the typical semiconductor laser diode is, through an outer lens, focused on an external device such as an optical fiber. Also, in the case of the laser semiconductor as illustrated in FIG. 1, an optical output in a section of the tapered waveguide 2 is high relative to the narrow waveguide 1, and thus the optical output is, through the outer lens, focused on the external device such as an optical fiber. At this point, a different focal distance of the beam in a vertical direction and a horizontal direction of the tapered waveguide 2 causes astigmatism. Particularly, when a single mode beam generated from the narrow waveguide 1 travels through the tapered waveguide 2, a wavefront of the beam crossing an upper surface of the tapered waveguide 2 is curved. However, since a thickness of the tapered waveguide 2 is even smaller than its length or width, a wavefront of the beam crossing a vertical plane with respect to the upper surface of the tapered waveguide 2 is substantially flat. That is, a focus of the former is formed further away from the external lens than that of the latter. To remove this astigmatism, the typical laser semiconductor requires a lens with a complicated structure, which increases a unit cost of a product.

In addition, in the case where the tapered waveguide 2 has the linearly increasing width, when the strength of a beam is increased, the interaction between carrier density and the strength of the beam causes spatial-hole burning (SHB), self-focusing, and filamentation phenomena.

### DISCLOSURE OF INVENTION

1. Technical Problem

The present invention provides a semiconductor laser diode having high output and high brightness.

The present invention also provides a semiconductor laser diode that can provide a single mode output of several W or more.

2. Technical Solution

Embodiments of the present invention provide semiconductor laser diodes including: at least one first waveguide having a narrow width; at least one second waveguide having a wide width wider; and at least one waveguide lens having an increasing width from the first waveguide toward the second waveguide and connecting the first waveguide to the second waveguide, wherein at least one sidewall of the waveguide lens connecting the first waveguide to the second waveguide may be curved.

In some embodiments, the at least one sidewall of the waveguide lens may include a continuously increasing radius of curvature from the first waveguide toward the second waveguide.

In other embodiments, the waveguide lens may include a sidewall shape forming a beam incident from the first waveguide to the second waveguide into a substantially parallel beam. For example, the sidewall shape of the waveguide lens may include a parabola.

In still other embodiments, the waveguide lens may include a sidewall shape causing a beam incident from the first waveguide to the second waveguide to converge into a range less than a maximum width of the waveguide lens. For example, the sidewall of the waveguide lens may include an ellipse.

In even other embodiments, the second waveguide may include a slab waveguide having a wider width than that of the waveguide lens. Alternately, the second waveguide may form a multi-mode waveguide. In this case, the second waveguide may include a substantially same width as a maximum width of the waveguide lens.

In yet other embodiments, the at least one first waveguide may include a couple of first waveguides spaced apart from each other, and the at least one waveguide lens may include a couple of waveguide lenses spaced apart form each other, wherein each of the couple of waveguide lenses may be disposed between each of the couple of first waveguides and the second waveguide. In addition, the couple of first waveguides and the couple of waveguide lenses may be arranged in a mirror symmetrical manner with respect to the second waveguide.

In further embodiments, the at least one first waveguide may include a distributed brag reflector (DBR) grating. Alternately, the at least one second waveguide may include a distributed feedback (DFB) grating.

In still further embodiments, the first waveguide and the waveguide lens may form a passive waveguide of a group III/V compound, and the second waveguide may be formed of a group III/V compound and used as a gain medium. The group III/V compound for the second waveguide may be same as the group III/V compound for the first waveguide and the waveguide lens.

In even further embodiments, the second waveguide may be formed of the same material as that of the first waveguide and the waveguide lens. For example, the first waveguide, the second waveguide, and the waveguide lens may be formed of a group III/V compound and used as a gain medium.

In yet further embodiments, the first waveguide and the waveguide lens may form a passive waveguide formed of a dielectric, and the second waveguide may be formed of a group III/V compound and used as a gain medium. The dielectric for the first waveguide and the waveguide lens may include at least one of silica and polymer materials.

### ADVANTAGEOUS EFFECTS

According to the present invention, provided is a semiconductor laser diode including a narrow waveguide, a wide waveguide, and a waveguide lens disposed there-between. According to embodiments, a waveguide lens may have a parabola or an ellipse. Accordingly, a single mode beam generated from a narrow waveguide can be incident to the wide waveguide in the substantially parallel form. The semiconductor laser diode according to the present invention can obtain an increased gain to generate a high output beam. In addition, the beam is incident to the wide waveguide in the parallel form, thereby greatly reducing the typical astigmatism and technical difficulties in a module process for an optical connection to an optical fiber.

In addition, the waveguide lens makes a parallel light incident from the wide waveguide to be effectively focused on the narrow waveguide. As a result, the semiconductor laser diode according to the present invention has the reduced waveguiding loss characteristics regardless of a traveling direction of a beam.

According to an embodiment, a narrow waveguide and a waveguide lens can be used as a passive waveguide. In this case, a non-linear phenomenon and a filamentation phenomenon caused by the increase of output strength are prevented, thereby achieving increased output and an improved single mode beam. Also, an anti-reflection thin film deposition is performed on the section of the narrow waveguide, and a high-reflection thin film deposition is performed on the section of the wide waveguide, thereby obtaining most output from the narrow waveguide. This makes it possible to obtain output light with reduced astigmatism, high output and high brightness relative to a typical structure.

According to an embodiment, a first waveguide is connected to a waveguide lens at an inclined angle toward an inclined sidewall of the waveguide lens, and only the inclined sidewall of the waveguide lens can be used to collimate a beam incident from the first waveguide to the waveguide lens.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a plan view illustrating a typical semiconductor laser diode;

FIG. 2 is a plan view illustrating a waveguide lens according to an embodiment of the present invention;

FIGS. 3 through 11 are plan views illustrating laser semiconductors according to embodiments of the present invention;

FIG. 12 is a plan view illustrating a model used for simulating output loss of a laser semiconductor according to an embodiment of the present invention;

FIG. 13 is a simulation graph illustrating characteristics of output loss according to an embodiment of the present invention; and

FIG. 14 is a plan view illustrating a laser semiconductor according to another embodiment of the present invention.

### MODE FOR THE INVENTION

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

In the specification, the dimensions of layers and regions are exaggerated for clarity of illustration. It will also be understood that when a layer (or film) is referred to as being ‘on’ another layer or substrate, it can be directly on the other layer or substrate, or intervening layers may also be present. Also, though terms like a first, a second, and a third are used to describe various regions and layers in various embodiments of the present invention, the regions and the layers are not limited to these terms. These terms are used only to tell one region or layer from another region or layer. Therefore, a layer referred to as a first layer in one embodiment can be referred to as a second layer in another embodiment. An embodiment described and exemplified herein includes a complementary embodiment thereof.

Hereinafter, it will be described about an exemplary embodiment of the present invention in conjunction with the accompanying drawings.

A semiconductor laser diode of the present invention may include at least one first waveguide having a narrow width, at least one second waveguide having a wide width, and at least one waveguide lens connecting them to each other. The waveguide lens may be configured such that a beam output from the first waveguide is incident to the second waveguide in a substantially parallel form or converges into a range less than a maximum width of the waveguide lens. To this end, a side wall of the waveguide lens may be formed with a continuously increasing radius of curvature (e.g., parabola or ellipse).

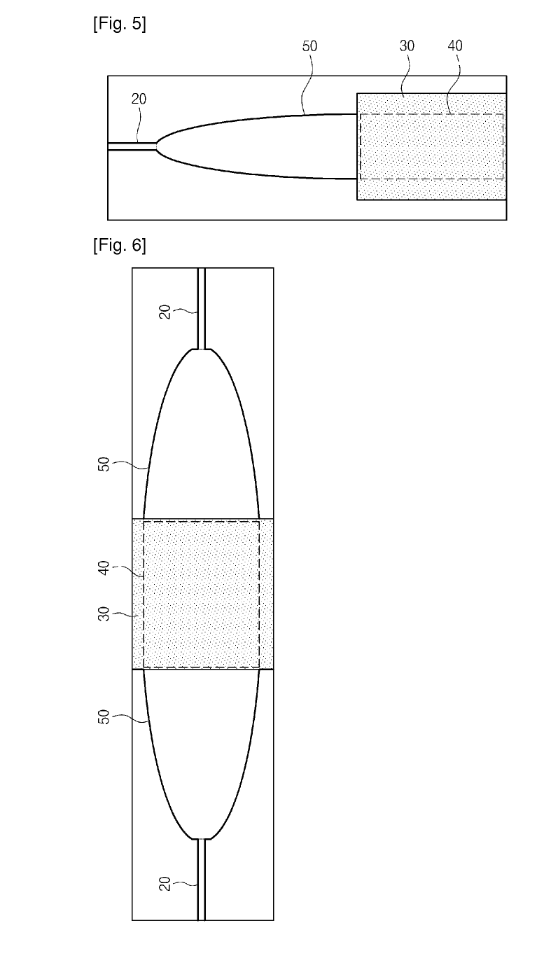

More particularly, referring to FIG. 2, a waveguide lens 50 will now be described according to an embodiment of the present invention. The waveguide lens 50 may have a parabola boundary. For example, as illustrated in FIG. 2, a side wall of the waveguide lens 50 may have a curved boundary formed by y²=4ax. Both ends of the waveguide lens 50 may be connected to a first waveguide 20 having a narrow width and a second waveguide 30 having a wide width at coordinates (a, 0) and (L, 0), respectively. The waveguide lens 50 may be a truncated parabola having a section passing through a focus, and a vertex (i.e., coordinates (0, 0)) of the parabola may be positioned on the first waveguide 20.

An incident beam from the first waveguide 20 to the waveguide lens 50 may travel in various directions through diffraction. However, the parabola waveguide lens 50 provides collimation of the beam. Particularly, when a traveling path of the beam crosses the side wall of the waveguide lens 50, the beam is reflected from a predetermined reflection point RP and travels along a new path. Here, when the side wall of the waveguide lens 50 has a parabola shape as described above, the new path of the reflected beam is parallel with the long axis of the first waveguide 20 irrespective of a position of the reflection point RP. Although a portion of the beam may have a path that does not cross the side wall of the first waveguide 20, when the length (i.e., L-a) of the waveguide lens 50 is sufficiently greater than its width 2b, the beam is substantially collimated.

Also, when a predetermined parallel beam from the second waveguide 30 is incident to the waveguide lens 50, according to the same geometrical optics as described above, the beam is reflected from the side wall of the waveguide lens 50 and then focused at an end of the first waveguide 20 positioned at the focus coordinates of the parabola.

According to another embodiment of the present invention, the waveguide lens 50 may have an ellipse-shaped side wall. The first waveguide 20 may be connected to an end of the waveguide lens 50 at a focus of the ellipse, and the second waveguide 30 may be connected to the other end of the waveguide lens 50 between the other focus of the ellipse and the center of the ellipse. In this case, an incident beam from the first waveguide 20 to the waveguide lens 50 is reflected from a predetermined reflection point and has a traveling path toward the other focus of the ellipse, and thus, beams converge into a range less than the maximum width of the waveguide lens 50. In the case where the eccentricity of an ellipse is great, the beams are substantially parallel with each other.

Also, when a predetermined beam from the second waveguide 30 are incident to the waveguide lens 50, according to the same geometrical optics as described above, the beam is reflected from the sidewall of the waveguide lens 50 and then focused at the end of the first waveguide 20 positioned at the focus of the ellipse.

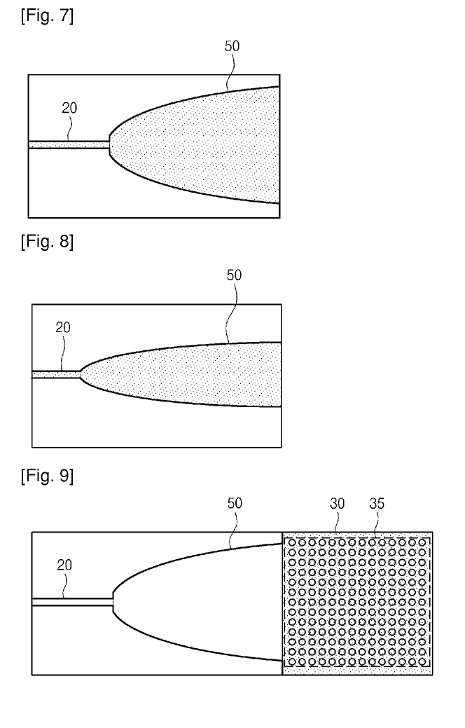

FIGS. 3 through 11 are plan views illustrating laser semiconductors according to embodiments of the present invention.

Referring to FIGS. 3 through 11, a laser semiconductor 100 includes a first waveguide 20, a second waveguide 30, and a waveguide lens 50 connecting them to each other. The first waveguide 20 may be configured to realize a single mode, and the second waveguide 30 may be configured to provide a high gain. To this end, a width of the second waveguide 30 may greater than that of the first waveguide 20.

The waveguide lens 50 may be formed to have the technical characteristics of the waveguide lens described with reference to FIG. 2. FIGS. 3, 6, 7, 9, 10 and 11 are the plan view illustrating the waveguide lens 50 having a parabola sidewall according to the embodiments of the present invention. FIGS. 4, 5, and 8 are the plan view illustrating the waveguide lens 50 having an ellipse sidewall according to the embodiments of the present invention.

Meanwhile, according to the embodiment of the present invention, the first waveguide 20 and the waveguide lens 50 may form a passive wave guide, and the second waveguide 30 may form a slab waveguide as a gain medium, as illustrated in FIGS. 3, 4, 5, 6, 9, 10 and 11. The gain medium provides an optical gain in a laser diode. The optical gain may be obtained through stimulated emission in electronic or molecular transitions from a high energy state to a low energy state. The slab waveguide may include a core layer having a wider width than the waveguide lens 50. The first waveguide 20 and a core layer of the waveguide lens 50 may be formed of at least one of group III/V compounds or dielectrics. According to the embodiment of the present invention, the dielectric may be at least one of silica and polymer materials. The core layer of the second waveguide 30 may be one of group III/V compounds, and an electrode 40 supplying a current for the optical gain may be disposed thereon.

When the first waveguide 20 and the waveguide lens 50 form a passive waveguide, spatial-hole burning (SHB) phenomenon does not occur, thereby preventing filamentation phenomenon caused by non-linear characteristics. Thus, a semiconductor laser diode according to this embodiment can generate a beam with more increased output and an improved single mode.

In addition, the first waveguide 20, the second waveguide 30, and the waveguide lens 50 may be formed of the same material. In this case, decreasing the number of processes can decrease manufacturing costs. Also, according to the embodiment of the present invention, the thickness of the first waveguide 20 may be substantially same as that of the waveguide lens 50, but the thickness of the second waveguide 30 may be substantially same as or different from that of the waveguide lens 50, depending on optical characteristics.

According to another embodiment of the present invention, as illustrated in FIGS. 7 and 8, the first waveguide 20 and the waveguide lens 50 may also be used as a gain medium like the second waveguide 30. Here, the first waveguide 20, the second waveguide 30, and the waveguide lens 50 may be formed of a group III/V compound. According to this embodiment, an additional process for forming a passive waveguide is not necessary, thereby reducing manufacturing costs.

According to the embodiment of the present invention, as illustrated in FIGS. 6, 10 and 11, the laser semiconductor 100 may include the couple of first waveguides 20 spaced apart from each other and the couple of waveguide lenses 50 disposed therebetween. The second waveguide 30 may be disposed between the couple of waveguide lenses 50, and another second waveguide may be further disposed there-between. The couple of first waveguides 20 and the couple of waveguide lenses 50 may be arranged in a mirror symmetrical manner with respect to the second waveguide 30.

According to the embodiment of the present invention, as illustrated in FIGS. 9 and 10, the second waveguide 30 may include a distributed feedback (DFB) grating 35. The distributed feedback grating 35, as is well known, may be a structure in a waveguide to serve as a grating, and the beam may have a single spatial frequency through the distributed feedback grating 35.

In addition, as illustrated in FIG. 11, the first waveguide 20 may include a distributed brag reflector (DBR) grating 25. As is well known, the distributed brag reflector grating 25, as a high-quality reflector used in a waveguide, may have a multi-layered structure where materials having a different refractive index are alternately disposed and provide periodic changes in an effective refractive index in a waveguide. The beam may have a single spatial frequency through the distributed brag reflector grating 25.

According to an embodiment of the present invention, referring to FIGS. 3, 4, 6, 9, 10 and 11, the second waveguide 30 may forms a slab waveguide. According to another embodiment of the present invention, referring to FIG. 5, the second waveguide 30 may be patterned with a predetermined width to realize predetermined multi-modes.

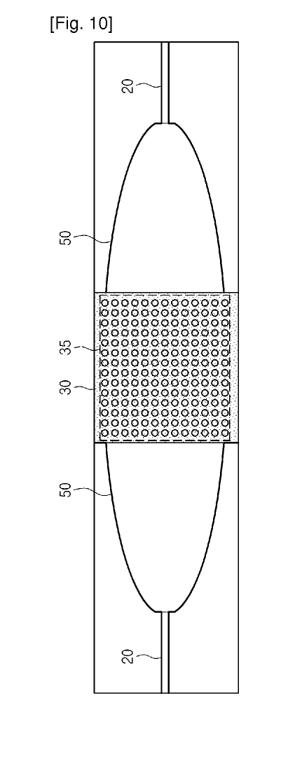

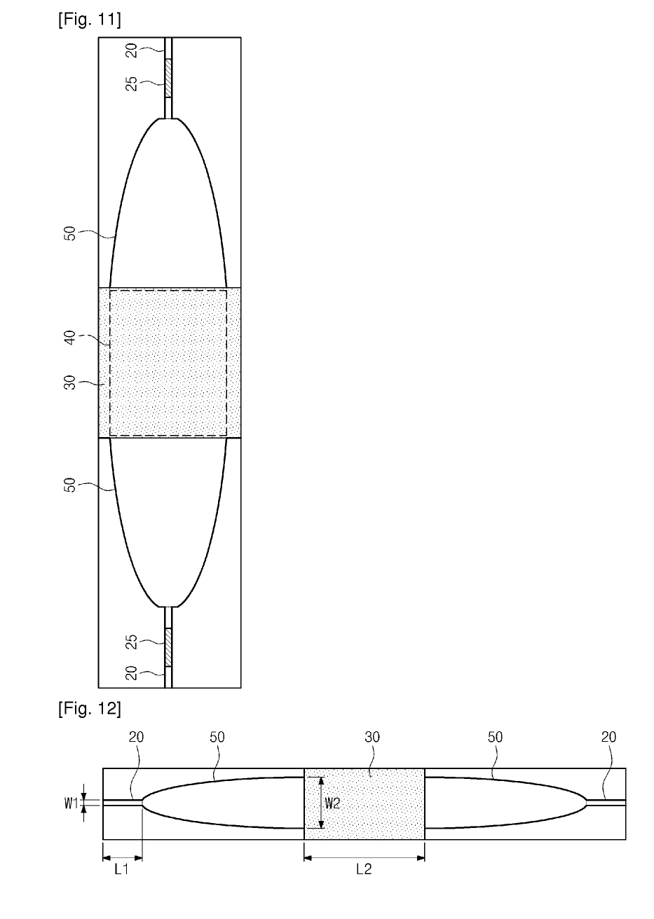

FIG. 12 is a plan view illustrating a model used for simulating output loss of a laser semiconductor according to an embodiment of the present invention. FIG. 13 is a simulation graph illustrating characteristics of simulated output loss according to an embodiment of the present invention.

Referring to FIG. 12, it was assumed that the laser semiconductor considered in simulation had a couple of first waveguides 20 and a couple of waveguide lenses 50 arranged in a symmetric manner with respect to a second waveguide 30, as described with reference to FIG. 6. It was also assumed that the waveguide lens 50 had a parabola sidewall. In addition, it was assumed that the first waveguides 20 and the waveguide lenses 50 had a refractive index of about 3.22, and the second waveguide 30 had a refractive index of about 3.55. It was also assumed that a width W1 and a length L1 of the first waveguides 20 were respectively about 1.5 micro meter and about 100 micro meter, and a maximum width W2 of the waveguide lenses 50 was about 35 micro meter, and the second waveguide 30 was a slab waveguide having a length L2 of about 500 micro meter. In addition, it was assumed that the waveguide lenses 50 and the first waveguides 20 were provided in a waveguide structure where their core layer and a lower clad layer under the core layer were partially etched (i.e., a deep ridge waveguide).

Referring to FIG. 13, waveguiding characteristics of a traveling beam between the first waveguides 20 in the model described with reference to FIG. 12 were simulated using a 2-dimensional beam propagation method (BPM). The beam traveled between the two first waveguides 20 without substantial loss, in which a waveguiding loss was about 0.06 dB.

Meanwhile, according to another simulation with a model having a length of the second waveguide 30 of about 1,000 micro meter, such a waveguiding loss was about 1.0 dB. As a result, when a maximum width of the waveguide lens 50 is about 35 micro meter, and a length of the second waveguide 30 ranges about 500 micro meter to about 1,000 micro meter, such a waveguiding loss was reduced to about 1.0 dB or less.

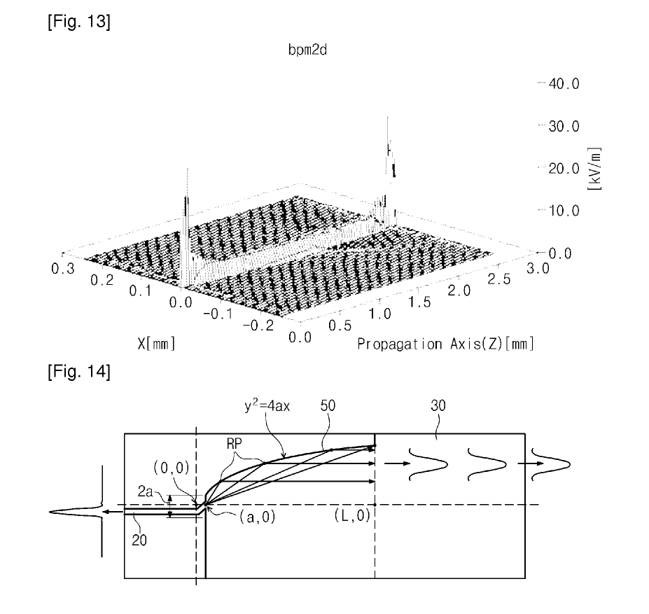

FIG. 14 is a plan view illustrating a laser semiconductor according to another embodiment of the present invention. For the convenience of description, the same technical features as those of the above description will be omitted.

Referring to FIG. 14, to direct a beam from a first waveguide 20 to a sidewall of a waveguide lens 50, the first waveguide 20 may be connected to the waveguide lens 50 at an inclined angle. Since the sidewall of the waveguide lens 50 has a parabola or an ellipse, a beam from the first waveguide 20 is totally reflected from the sidewall of the waveguide lens 50 to travel along a collimated path.

Meanwhile, since the first waveguide 20 is connected to the waveguide lens 50 at the inclined angle, all beams from the first waveguide 20 are substantially collimated. As a result, a semiconductor laser diode according to this embodiment has more reduced waveguiding loss characteristics than those of the semiconductor laser diodes according to the preceding embodiments.

In addition, since only the sidewall of the waveguide lens 50 is used for the collimation of the beams, only the sidewall of the waveguide lens 50 corresponding to the incident beams may have a shape (e.g., an ellipse or a parabola) for the collimation.

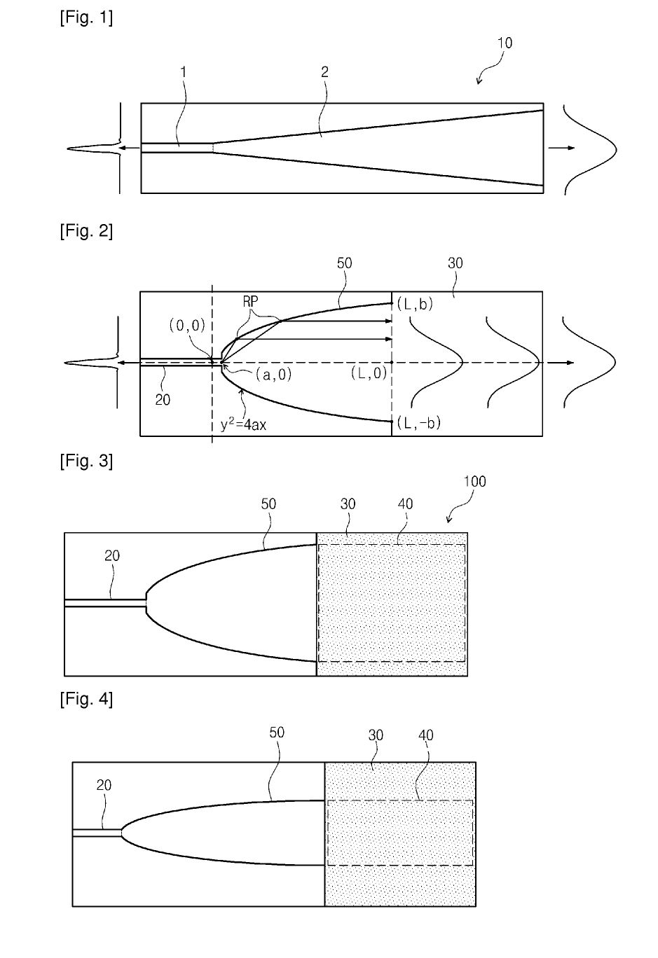

Meanwhile, this embodiment may include the same technical features as those relating to the material, the width and the waveguiding mode of the first and the second waveguides 20 and 30 and the waveguide lens 50 described with reference to FIGS. 1 through 13. Also, the first and the second waveguides 20 and 30 may include the same technical features as those relating to the gratings described with reference to FIGS. 9 through 11.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A semiconductor laser diode comprising:
at least one first waveguide of a single mode having a first width;
at least one second waveguide having a second width wider than the first width; and
at least one waveguide lens having an increasing width from the first waveguide toward the second waveguide and connecting the first waveguide to the second waveguide, wherein at least one sidewall of the waveguide lens connecting the first waveguide to the second waveguide is curved.

2. The semiconductor laser diode of claim 1, wherein the at least one sidewall of the waveguide lens comprises a continuously increasing radius of curvature from the first waveguide toward the second waveguide.

3. The semiconductor laser diode of claim 1, wherein the waveguide lens comprises a sidewall shape forming a beam incident from the first waveguide to the second waveguide into a substantially parallel beam.

4. The semiconductor laser diode of claim 3, wherein the sidewall shape of the waveguide lens comprises a parabola.

5. The semiconductor laser diode of claim 1, wherein a sidewall shape of the waveguide lens is configured to converge a beam, which travels from the first waveguide to the second waveguide, into a region whose width is narrower than a maximum width of the waveguide lens.

6. The semiconductor laser diode of claim 5, wherein the sidewall shape of the waveguide lens comprises an ellipse.

7. The semiconductor laser diode of claim 1, wherein the second waveguide comprises a slab waveguide having a wider width than that of the waveguide lens.

8. The semiconductor laser diode of claim 1, wherein the second waveguide forms a multi-mode waveguide.

9. The semiconductor laser diode of claim 8, wherein the second waveguide comprises a substantially same width as a maximum width of the waveguide lens.

10. The semiconductor laser diode of claim 1, wherein at least the one first waveguide comprises a couple of first waveguides spaced apart from each other, and at least the one waveguide lens comprises a couple of waveguide lenses spaced apart form each other,
wherein each of the couple of waveguide lenses is disposed between each of the couple of first waveguides and the second waveguide.

11. The semiconductor laser diode of claim 10, wherein the couple of first waveguides and the couple of waveguide lenses are arranged in a mirror symmetrical manner with respect to the second waveguide.

12. The semiconductor laser diode of claim 1, wherein the at least one first waveguide comprises a distributed brag reflector (DBR) grating.

13. The semiconductor laser diode of claim 1, wherein the at least one second waveguide comprises a distributed feedback (DFB) grating.

14. The semiconductor laser diode of claim 1, wherein the first waveguide and the waveguide lens form a passive waveguide of a group III/V compound, and the second waveguide is formed of a group III/V compound and used as a gain medium.

15. The semiconductor laser diode of claim 1, wherein the first waveguide, the second waveguide, and the waveguide lens are formed of a group III/V compound and used as a gain medium.

16. The semiconductor laser diode of claim 1, wherein the first waveguide and the waveguide lens form a passive waveguide formed of a dielectric, and the second waveguide is formed of a group III/V compound and used as a gain medium.

17. The semiconductor laser diode of claim 16, wherein the dielectric for the first waveguide and the waveguide lens comprises at least one of silica and polymer materials.

18. The semiconductor laser diode of claim 1, wherein the first waveguide is connected to the waveguide lens at an inclined angle toward the inclined sidewall of the waveguide lens, and only the inclined sidewall of the waveguide lens is used to collimate a beam incident from the first waveguide to the waveguide lens.

19. The semiconductor laser diode of claim 10, wherein the first waveguide and the waveguide lens form a passive waveguide of a group III/V compound, and the second waveguide is formed of a group III/V compound and used as a gain medium.
